(19) United States
(12) Patent Application Publication
(10) Pub. No.: US 2016/0035568 A1
(43) Pub. Date: Feb. 4, 2016

(54) METHOD OF MANUFACTURING TRANSITION METAL CHALCOGENIDE THIN FILM

(71) Applicant: ELECTRONICS AND TELECOMMUNICATIONS RESEARCH INSTITUTE, Daejeon (KR)

(72) Inventors: Yong-Duck CHUNG, Daejeon (KR); DAEHYUNG CHO, Daejeon (KR); Woo Jung LEE, Chungcheongnam-do (KR); Won Seok HAN, Daejeon (KR)

(73) Assignee: ELECTRONICS AND TELECOMMUNICATIONS RESEARCH INSTITUTE, Daejeon (KR)

(21) Appl. No.: 14/812,856

(22) Filed: Jul. 29, 2015

(30) Foreign Application Priority Data
Aug. 4, 2014 (KR) 10-2014-0099924
May 27, 2015 (KR) 10-2015-0074205

(51) Int. Cl. H01L 21/02

(52) U.S. Cl. CPC H01L 21/02568; H01L 21/0262; H01L 21/0259

(57) ABSTRACT

Provided is a method of manufacturing a transition metal chalcogenide thin film including providing a substrate having a transition metal film thereon, evaporating a chalcogen source to form a chalcogen material having a second molecular structure, decomposing the chalcogen material having the second molecular structure to form the chalcogen material having the first molecular structure, in which the first molecular structure includes relatively less atoms than the second molecular structure, and providing the chalcogen material having the first molecular structure on a transition metal film.

### CROSS-REFERENCE TO RELATED APPLICATIONS

This U.S. non-provisional patent application claims priority under 35 U.S.C. §119 of Korean Patent Application Nos. 10-2014-0099924, filed on Aug. 4, 2014, and 10-2015-0074205, filed on May 27, 2015, the entire contents of which are hereby incorporated by reference.

### BACKGROUND

The present disclosure herein relates to a method of manufacturing a metal compound thin film, and more particularly, to a method of manufacturing a transition metal chalcogenide.

Speed improvement and integration of a silicon (Si)-based electronic device or a groups III-V-based optical device require development of a new material having a high mobility with development of nano thin film technologies. Characteristics of a typical semiconductor device are determined by a carrier mobility in a thin film used as a channel of the device, and factors for determining the mobility are phonon scattering, ionized impurity scattering, interface roughness, and grain boundary scattering, and the like. Since a defect and roughness of an interface between a device channel and an insulating layer are important factors determining mobility, researches to improve the factors and synthesis and development of a material with improved mobility are regarded as very important research topics.

At present, as a group of materials showing potential for breakthrough in a TFT field in addition to a silicon-based material, there is an MX₂ (M=Mo, Zn, X═S, Se) that is a transition metal dichalcogenide (TMDCs) having high mobility and a low-dimensional layered structure, and particularly, an MoS₂ thin film exhibits similar characteristics to graphene, thus receiving strong interest from academia and industry. A transition metal chalcogenide thin film has excellent electrical characteristics in a low-dimensional structure as well as mechanical properties. In particular, molybdenum disulfide (MoS₂) has advantages of excellent luminous efficiency, high carrier mobility, and a high on/off ratio. It was reported that a bulk MoS₂ has a nonlinear band gap level of 1.2 eV and a monolayer MoS₂ may have a maximum band gap of 1.8 eV, a carrier mobility of 200-350 cm²/Vs, and a high on/off ratio of 10⁶-10⁸. So, the monolayer MoS₂ is expected to be stably applied to developments of a switching device, an optoelectronic device, a memory, a signal amplifier, and a variety of light-related sensors.

### SUMMARY

The present disclosure provides a method capable of forming a transition metal chalcogenide thin film at a low temperature.

An embodiment of the inventive concept provides a method of manufacturing a transition metal chalcogenide thin film, the method including: providing a substrate having a transition metal film thereon; and providing a chalcogen material having a first molecular structure on the transition metal film, and the providing the chalcogen material having the first molecular structure includes: evaporating a chalcogen source to form a chalcogen material having a second molecular structure; and decomposing the chalcogen material having the second molecular structure to form the chalcogen material having the first molecular structure, and the first molecular structure includes relatively less atoms than the second molecular structure.

In an embodiment, the method of manufacturing a transition metal chalcogenide thin film may further include performing a first heating process of the substrate.

In an embodiment, a temperature of the first heating process may range from about 50° C. to about 550° C.

In an embodiment, the providing the chalcogen material having the first molecular structure may be performed after the substrate having the transition metal film thereon is exposed to air.

In an embodiment, the evaporating the chalcogen source may include performing a second heating process of the chalcogen source.

In an embodiment, the decomposing the chalcogen material having the second molecular structure may include performing a third heating process of the chalcogen material having the second molecular structure, and a temperature of the third heating process may be higher than that of the second heating process.

In an embodiment, the transition metal film may be a molybdenum (Mo) film.

In an embodiment, the chalcogen material may be sulfur (S).

In an embodiment, the transition metal chalcogenide thin film may include a structure of a mono-layer or a double layer.

In an embodiments of the inventive concept, a method of manufacturing a transition metal chalcogenide thin film for achieving the above-mentioned problems includes providing a transition metal material and a chalcogen material having a first molecular structure on a substrate, and the providing the chalcogen material having the first molecular structure includes: evaporating a chalcogen source to form a chalcogen material having a second molecular structure; and decomposing the chalcogen material having the second molecular structure to form the chalcogen material having the first molecular structure, and the first molecular structure includes relatively less atoms than the second molecular structure.

In an embodiment, the method of manufacturing a transition metal chalcogenide thin film may further include performing a first heating process of the substrate.

In an embodiment, a temperature of the first heating process may range from about 50° C. to about 550° C.

In an embodiment, the evaporating the chalcogen source may include performing a second heating process of the chalcogen source.

In an embodiment, the decomposing the chalcogen material having the second molecular structure may include performing a third heating process of the chalcogen material having the second molecular structure, and a temperature of the third heating process may be higher than that of the second heating process.

In an embodiment, the transition metal film may be molybdenum (Mo).

In an embodiment, the chalcogen material may be sulfur (S).

In an embodiment, the transition metal chalcogenide thin film may include a structure of a mono-layer or a double layer.

### BRIEF DESCRIPTION OF THE FIGURES

The accompanying drawings are included to provide a further understanding of the inventive concept, and are incorporated in and constitute a part of this specification. The drawings illustrate exemplary embodiments of the inventive concept and, together with the description, serve to explain principles of the inventive concept. In the drawings:

FIGS. 1 to 3 illustrate a apparatus and process of cracking a chalcogen material according to an embodiment of the inventive concept;

FIGS. 4 to 7 illustrate a method of manufacturing a transition metal chalcogenide thin film according to an embodiment of the inventive concept;

FIG. 8 illustrates a method of manufacturing a transition metal chalcogenide thin film according to another embodiment of the inventive concept;

FIGS. 9 to 12 illustrate an application example of a method of manufacturing a transition metal chalcogenide thin film to a manufacturing apparatus according to an embodiment of the inventive concept;

FIG. 13 illustrates an application example of a method of manufacturing a transition metal chalcogenide thin film to a manufacturing apparatus according to another embodiment of the inventive concept; and

FIGS. 14 to 17 illustrate another application example of a method of manufacturing a transition metal chalcogenide thin film to a manufacturing apparatus according to an embodiment of the inventive concept.

### DETAILED DESCRIPTION

Exemplary embodiments of the inventive concept will be described below in more detail with reference to the accompanying drawings. The inventive concept may, however, be embodied in different forms and should not be construed as limited to the embodiments set forth herein. Rather, these embodiments are provided so that this disclosure will be thorough and complete, and will fully convey the scope of the inventive concept to those skilled in the art.

Hereinafter, exemplary embodiments of the inventive concept will be described in detail with reference to the accompanying drawings.

The objects, other objects, features, and advantages of the present invention will be readily understood through embodiments related to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art.

In the specification, it will be understood that when a layer (or film) is referred to as being ‘on’ another layer (or film) or substrate, it can be directly on the other layer (or film) or substrate, or intervening layers (or film) may also be present.

Also, in the drawings, the thickness or size of each element are exaggerated for clarity of illustration. Although the terms, such as first, second, and third may be used herein to describe various directions, films (or layers), and the like, the directions, films (or layers), and the like should not be limited by these terms. These terms are used only to discriminate one direction or film (or layer) from another direction or film (layer). Therefore, a film referred to as a first film (or layer) in one embodiment can be referred to as a second film (or layer) in another embodiment. An embodiment described and exemplified herein includes a complementary embodiment thereof. As used herein, the term ‘and/or’ includes any and all combinations of one or more of the associated listed items. Like reference numerals refer to like elements throughout the specification.

Hereinafter, embodiments of the inventive concept will be described in detail with reference to drawings.

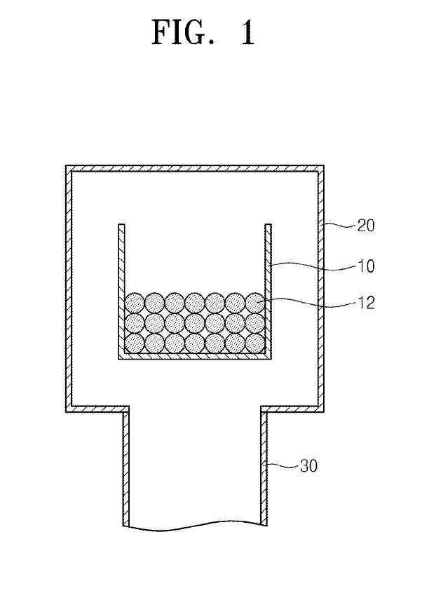

FIGS. 1 to 3 illustrate an apparatus and process of cracking a chalcogenide material according to an embodiment of the inventive concept.

Referring to FIG. 1, a first heating part 20 including a storing part 10 may be provided. The first heating part 20 may have a shape of a half-open tube having an opening on one side. The storing part 10 may include a chalcogen source 12 thereinside. The chalcogen source 12 may be a chalcogen material in solid or liquid form. The storing part 10 may include an opening on one side thereof. The chalcogen source 12 may move in and out of the storing part 10 through the opening of the storing part 10. A second heating part 30 may extend from the opening of the first heating part 20. The second heating part 30 may have a shape of an open tube having openings on both sides thereof.

Hereinafter, a cracking process will be described in detail. A case in which the chalcogen source 12 is sulfur (S) is described as an example, but the inventive concept is not limited thereto and another chalcogen material may also be an object for a cracking process.

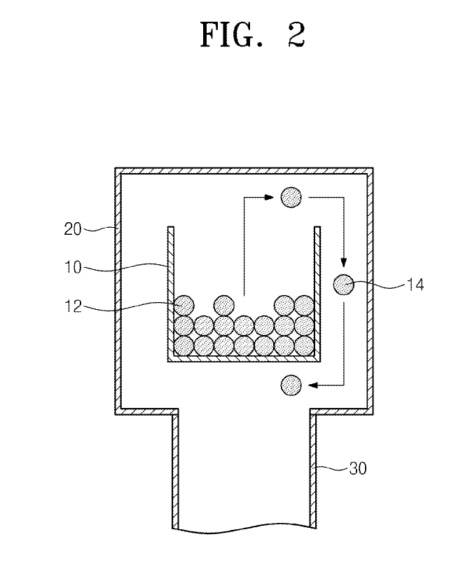

Referring to FIG. 2, sulfur (S) 12 may be provided inside the storing part 10. The sulfur 12 may be in solid or liquid form. In one example, the sulfur 12 in powder form may be provided inside the storing part 10. The sulfur 12 may be heated to a first temperature by the first heating part 20. In one example, the first temperature may range from about 150° C. to about 200° C. The sulfur 12 has a melting point of about 115° C., thus being able to be in liquid form at from about 150° C. to about 200° C. The sulfur in liquid form is evaporated to become sulfur 14 having a second molecular structure in gas form. The second molecular structure may have relatively more atoms than a first molecular structure to be described below. As an example, the second molecular structure may be S₈. The sulfur 14 having the second molecular structure may move to the second heating part 30 along an inside of the first heating part 20.

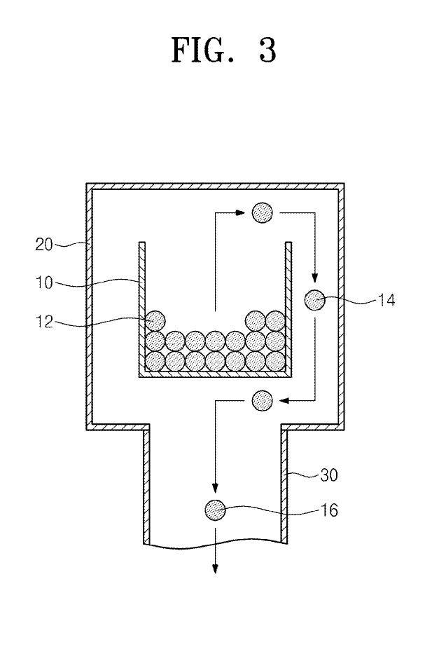

Referring to FIG. 3, the sulfur 14 having the second molecular structure is heated at a second temperature by the second heating part 30 to become sulfur 16 having the first molecular structure. The second temperature may range from about 700° C. to about 1000° C. The first molecular structure may have relatively less sulfur atoms than the second molecular structure. For example, the first molecular structure may be any one structure selected from S₂, S₃, and S₄. The first and second temperatures are illustratively provided, and not limited thereto. The sulfur 16 having the first molecular structure may have high reactivity to form a compound with a transition metal to be described below. Therefore, according to a cracking process according to the inventive concept, the sulfur 16 having the first molecular structure having excellent reactivity may be formed.

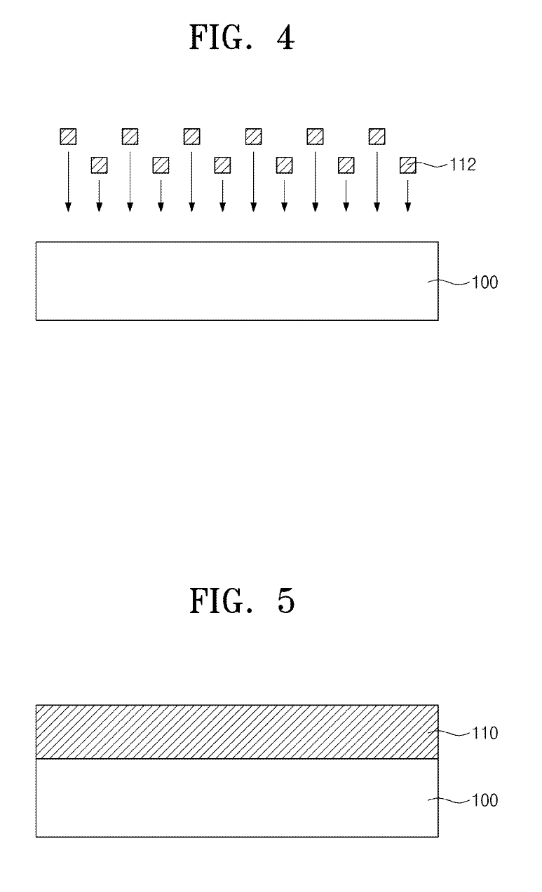

FIGS. 4 to 7 illustrate a method of manufacturing a transition metal chalcogenide thin film according to an embodiment of the inventive concept.

Referring to FIG. 4, a transition metal material 112 may be provided on a substrate 100. The substrate 100 may include any one selected from a glass substrate, a semiconductor substrate, a metal substrate, a ceramic substrate, and a plastic substrate. The transition metal material 112 may include, for example, molybdenum (Mo) or zinc (Zn).

Referring to FIG. 5, a transition metal film 110 may be formed on the substrate 100 through providing the transition metal material 112. The transition metal film 110 may react with a chalcogen material to be described below to form a transition metal chalcogenide. The transition metal film 110 may include a transition metal, for example, molybdenum (Mo) or zinc (Zn). A process of forming the transition metal film 110 may include a vacuum deposition method such as an evaporation method or a sputtering method. In one example, the process of forming the transition metal film 110 may include a sputtering process. For example, the process of forming the transition metal film 110 may be a sputtering process using molybdenum (Mo) as a sputtering target. The molybdenum (Mo) material may be separated from the sputtering target to be provided on the substrate 100. Accordingly, the molybdenum (Mo) film may be formed on the substrate 100. In one embodiment, the thickness of the transition metal film 110 (for example, a molybdenum (Mo) film) may range from about 1 nm to about 110 nm.

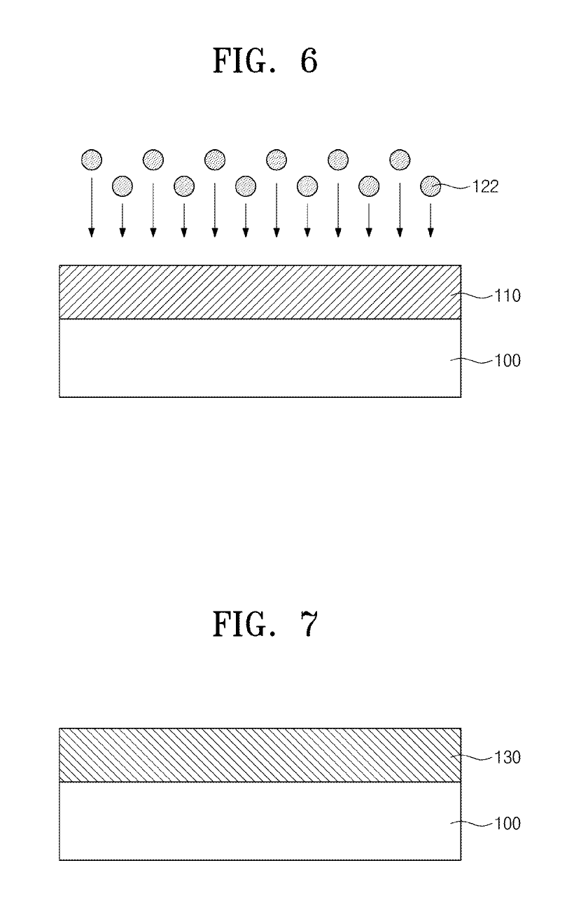

Referring to FIG. 6, a chalcogen material 122 may be provided on the transition metal film 110. In one example, the chalcogen material 122 may include sulfur (S) or selenium (Se). The chalcogen material 122 may be provided on the transition metal film 110 through the cracking process described with reference to FIGS. 1 to 3. The chalcogen material 122 subjected to the cracking process may have high reactivity.

The chalcogen material 122 and the transition metal film 110 may be heated. The heating process may include heating the substrate 100 to a third temperature. In one example, the third temperature may range from about 50° C. to about 550° C. When the second temperature of the cracking process described with reference to FIGS. 1 to 3 is about 1,000° C., the third temperature may range from about 50° C. to about 350° C. Through the heating process, the reactivity of the chalcogen material 122 and the transition metal film 110 may be enhanced. The heating process may start before or after the chalcogen material 122 and/or the transition metal film 110 are/is provided on the substrate and may continue until at least a desired transition metal chalcogenide thin film is formed.

Referring to FIG. 7, a transition metal chalcogenide thin film 130 may be formed on the substrate 100 through the processes of FIGS. 4 to 6. In one embodiment, the transition metal chalcogenide thin film 130 may be a MoS₂ thin film. The MoS₂ thin film may have a low-rise structure (for example, a mono-layer or a double layer). The mono-layered MoS₂ thin film may include S atoms at lower and upper portions thereof and Mo atoms at a middle portion thereof. The Mo atoms may be covalently bonded to the adjacent S atoms. The MoS₂ film having an n layer structure may be formed as n number of mono-layered MoS₂ films are bonded by van der Waals bonding. MoS₂ having a low-rise structure may have excellent carrier mobility.

According to the present embodiment, the transition metal chalcogenide thin film 130 having a low-rise structure may be formed at a low temperature (for example, from about 50° C. to about 350° C.). The transition metal chalcogenide thin film 130 having a low-rise structure may have excellent carrier mobility. In addition, without using a hydrogen compound (H₂S, H₂Se, or H₂Te) having toxicity, the chalcogen material 122 may be provided on the transition metal film 110.

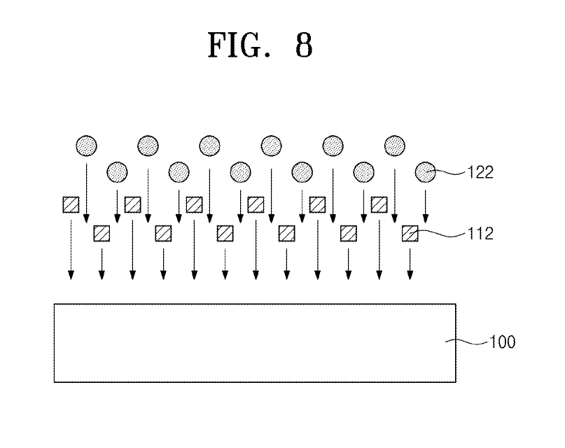

FIG. 8 illustrates a method of manufacturing a transition metal chalcogenide thin film according to another embodiment of the inventive concept. For simplicity of explanation, explanation about substantially same as the embodiments described with reference to FIGS. 4 to 7 will not be repeated.

Referring to FIG. 8, a transition metal material 112 and a chalcogen material 122 may be provided on a substrate 100 at the same time. However, “provided at the same time” may not necessarily mean that the two materials 112 and 122 are provided at the exact same time, but that the chalcogen material 122 (or the transition metal material 112) may be provided during the provision of the transition metal material 112 (or the chalcogen material 122). The process of providing the transition metal material 112 and the chalcogen material 122 may be substantially same as the process of providing the transition metal material 112 and the chalcogen material 122 described with reference to FIGS. 4 to 7.

The transition metal material 112 and chalcogen material 122 may be heated to a third temperature. The process and temperature of heating the transition metal material 112 and the chalcogen material 122 may be substantially same as the process and temperature of heating the transition metal film 110 and the chalcogen material 122 described with reference to FIGS. 4 to 7. Accordingly, as described in FIG. 7, a transition metal chalcogenide thin film 130 having a low-rise structure may be formed. The transition metal chalcogenide thin film 130 having a low-rise structure may have excellent carrier mobility.

According to the present embodiment, the transition metal chalcogenide thin film 130 having a low-rise structure may be formed at a low temperature (for example, from about 50° C. to about 350° C.). In addition, without using a hydrogen compound (H₂S, H₂Se, or H₂Te) having toxicity, the chalcogen material 122 may be provided on the substrate 100.

Hereinafter, application examples of the method of manufacturing a transition metal chalcogenide thin film according to the inventive concept will be described.

### Application Example 1

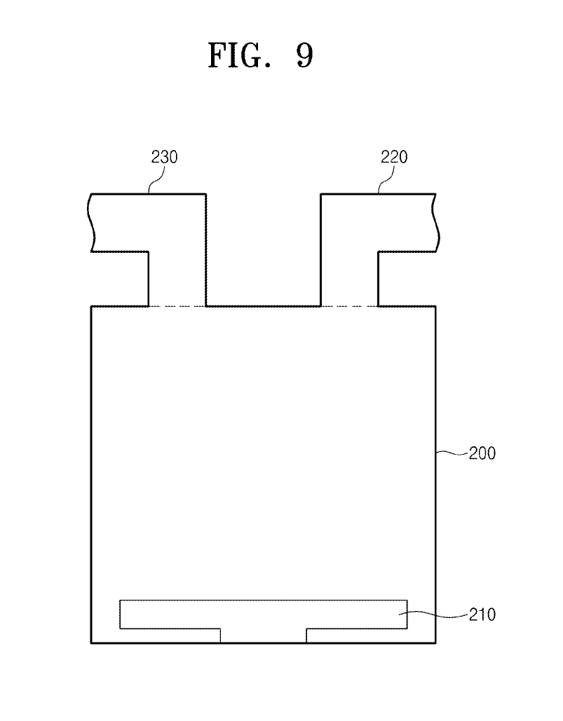

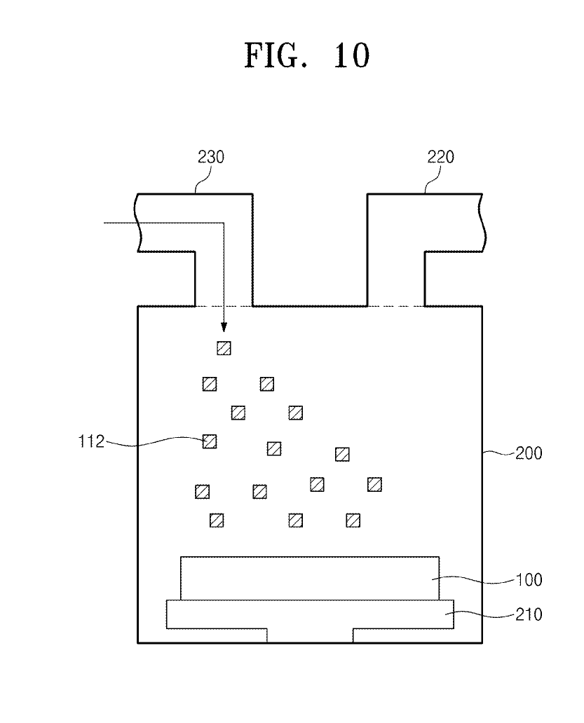

FIGS. 9 to 12 illustrate an application example of a method of manufacturing a transition metal chalcogenide thin film to a manufacturing apparatus according to an embodiment of the inventive concept. For simplicity of explanation, explanation about substantially same as the embodiments described with reference to FIGS. 4 to 7 will not be repeated.

Referring to FIG. 9, a chamber 200 including a substrate part 210 thereinside may be provided. The chamber 200 may include two openings. In one example, the openings may be provided in an upper portion of the chamber 200. A transition metal material supply device 230 and a chalcogen material supply device 220 may extend or be connected at each of the openings of the chamber 200.

Referring to FIG. 10, the substrate 100 may be provided on the substrate part 210. The substrate 100 may include any one selected from a glass substrate, a semiconductor substrate, a metal substrate, a ceramic substrate, and a plastic substrate.

A transition metal material 112 may be provided from the transition metal material supply device 230 to the substrate 100. In one example, the transition metal material 112 may be provided from the transition metal material supply device 230 including an evaporation deposition device to the substrate 100. For example, the transition metal material 112 may be molybdenum (Mo). Accordingly, the molybdenum (Mo) film may be formed on the substrate 100. In another example, the transition metal material 112 may be provided on the substrate 100 by a sputtering process. In this case, a sputtering device (not shown) may be provided inside the chamber and the transition metal material supply device 230 may not be provided.

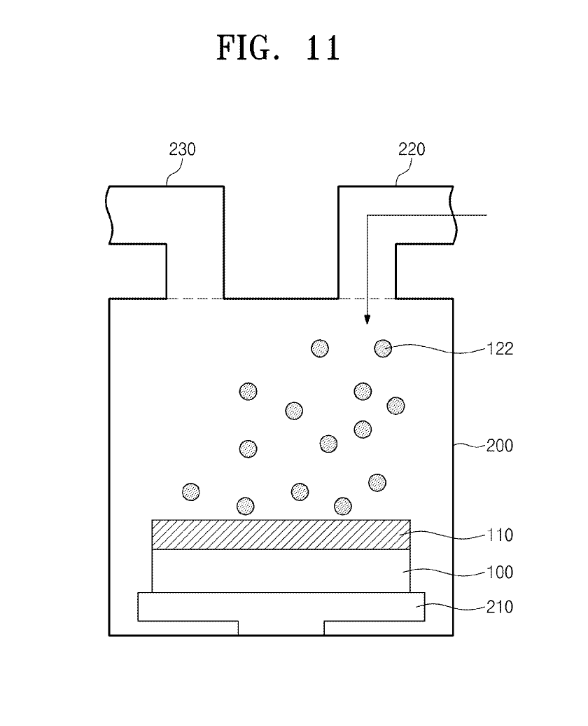

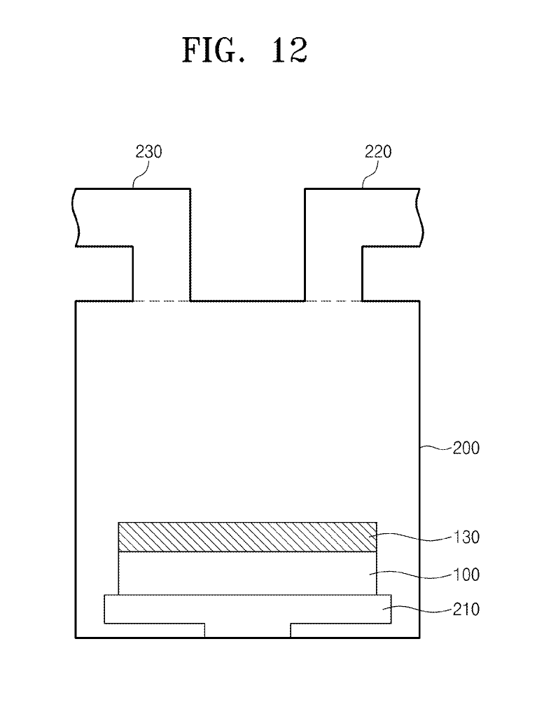

Referring to FIG. 11, a chalcogen material 122 may be provided on the transition metal film 110 from the chalcogen material supply device 220 through a process of FIG. 10. In one example, the chalcogen material supply device 220 may include a cracking device (not shown). The cracking device (not shown) may be substantially same as the cracking device of the embodiment described with a reference to FIGS. 1 to 3. For example, a sulfur gas 16 having the first molecular structure of an embodiment described with reference to FIGS. 1 to 3 may be provided on a molybdenum (Mo) film.

The chalcogen material 122 and the transition metal film 110 may be heated. The heating process may include heating the substrate part 210 to the third temperature. The heating process may be performed simultaneously with or after the provision of the chalcogen material 122. In one example, the third temperature may range from about 50° C. to about 550° C. When the second temperature of the cracking process substantially same as the cracking device of FIGS. 1 to 3 is about 1,000° C., the third temperature may range from about 50° C. to about 350° C. Through the heating process, the reactivity of the chalcogen material 122 and the transition metal film 110 may be enhanced.

Referring to FIG. 12, a transition metal chalcogenide thin film 130 may be formed on the substrate 100 through the processes of FIGS. 9 to 11. In one embodiment, the transition metal chalcogenide thin film 130 may be a MoS₂ thin film. The MoS₂ thin film may be a low-rise structure (for example, a mono-layer or a double-layer). The mono-layered MoS₂ thin film may include S atoms at lower and upper portions thereof and Mo atoms at a middle portion thereof. The Mo atoms may be covalently bonded to the adjacent S atoms. The MoS₂ film having an n layer structure may be formed as n number of mono-layered MoS₂ films are bonded by van der Waals bonding. MoS₂ having a low-rise structure may have excellent carrier mobility.

### Application Example 2

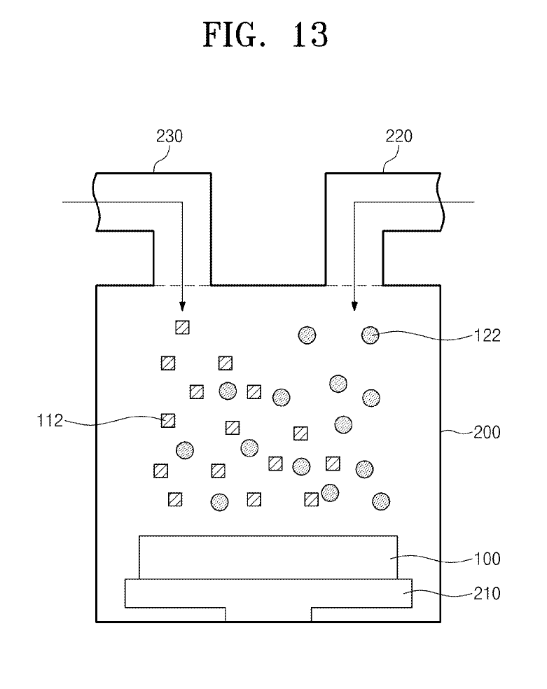

FIG. 13 illustrates an application example of a method of manufacturing a transition metal chalcogenide thin film to a manufacturing apparatus according to another embodiment of the inventive concept. For simplicity of explanation, explanation about substantially same as the embodiment described with reference to FIG. 8 and the application example described with reference to FIGS. 9 to 12 will not be repeated.

Referring to FIG. 13, the transition metal material 112 and the chalcogen material 122 may be provided from the transition metal material supply device 230 and the chalcogen material supply device 220 to the substrate 100 at the same time. However, “provided at the same time” may not necessarily mean that the two materials 112 and 122 are provided at the exact same time but that the chalcogen material 122 (or the transition metal material 112) may be provided during the provision of the transition metal material 112 (or the chalcogen material 122).

The transition metal material 112 and chalcogen material 122 may be heated. The heating process may be performed simultaneously with or after the provision of the chalcogen material 122. The heating process may be substantially same as the heating process described with reference to FIGS. 9 to 12. Accordingly, as described in FIG. 12, the transition metal chalcogenide thin film 130 may be formed on a substrate 100.

### Application Example 3

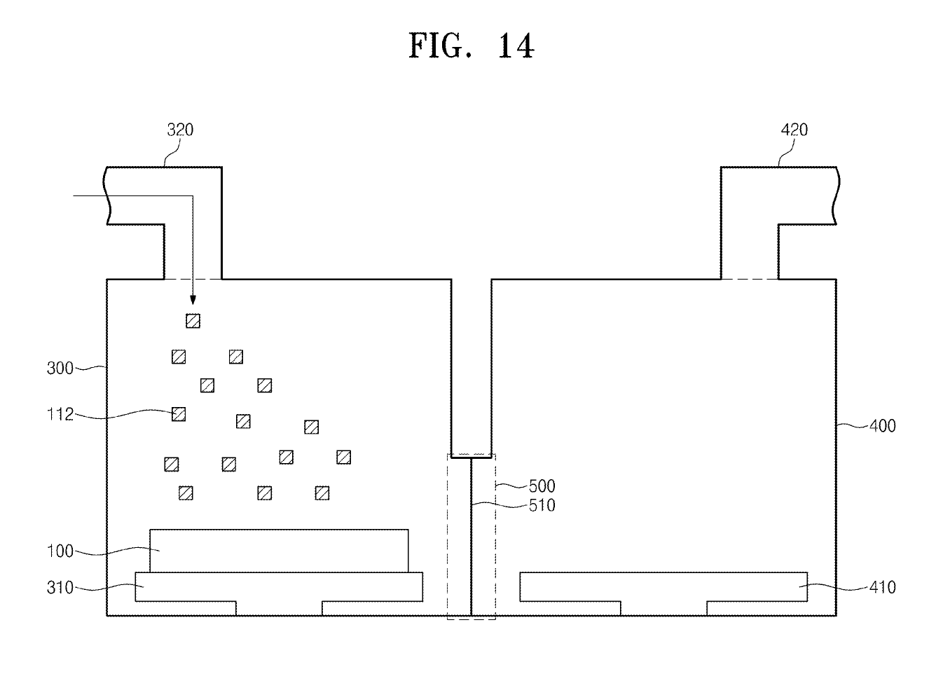

FIGS. 14 to 17 illustrate another application example of a method of manufacturing a transition metal chalcogenide thin film to a manufacturing apparatus according to an embodiment of the inventive concept. For simplicity of explanation, explanation about substantially same as the embodiment described with reference to FIGS. 4 to 7 and the application example described with reference to FIGS. 9 to 12 will not be repeated.

Referring to FIG. 14, a first chamber 300 and a second chamber 400 which are connected through a sample moving part 500 to each other may be provided. The transition metal material supply device 320 may be connected to one side of the first chamber 300. The first chamber 300 may include a first substrate part 310 thereinside. The chalcogen material supply device 420 may be connected to one side of the second chamber 400. The second chamber 400 may include a second substrate part 410 thereinside.

The substrate 100 may be provided on the first substrate part 310.

The transition metal material 112 may be provided from the transition metal material supply device 320 to the substrate 100. The process of providing the transition metal material 112 may be substantially same as the process of providing the transition metal material 112 described with reference to FIGS. 9 to 12.

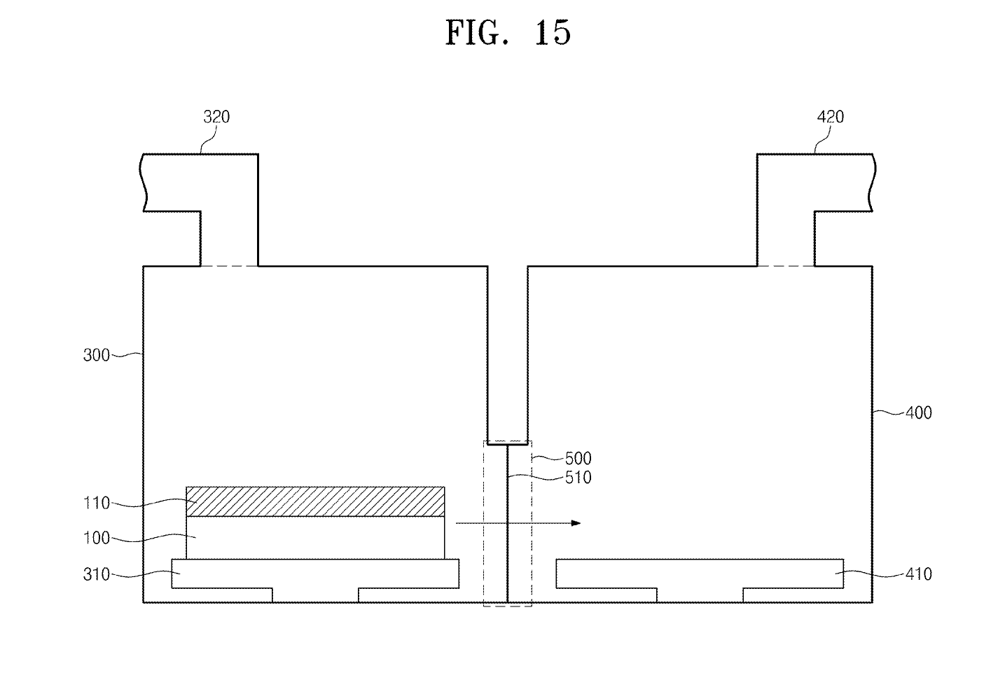

Referring to FIG. 15, the substrate 100 having a transition metal film 110 formed through a process of FIG. 14 may be moved to the second chamber 400. The substrate 100 may be moved through the sample moving part 500. The sample moving part 500 may include a blocking part 510 capable of opening and closing. When the substrate 100 moves, the blocking part 510 may be opened. When the substrate 100 finishes moving, the blocking part 510 may be closed.

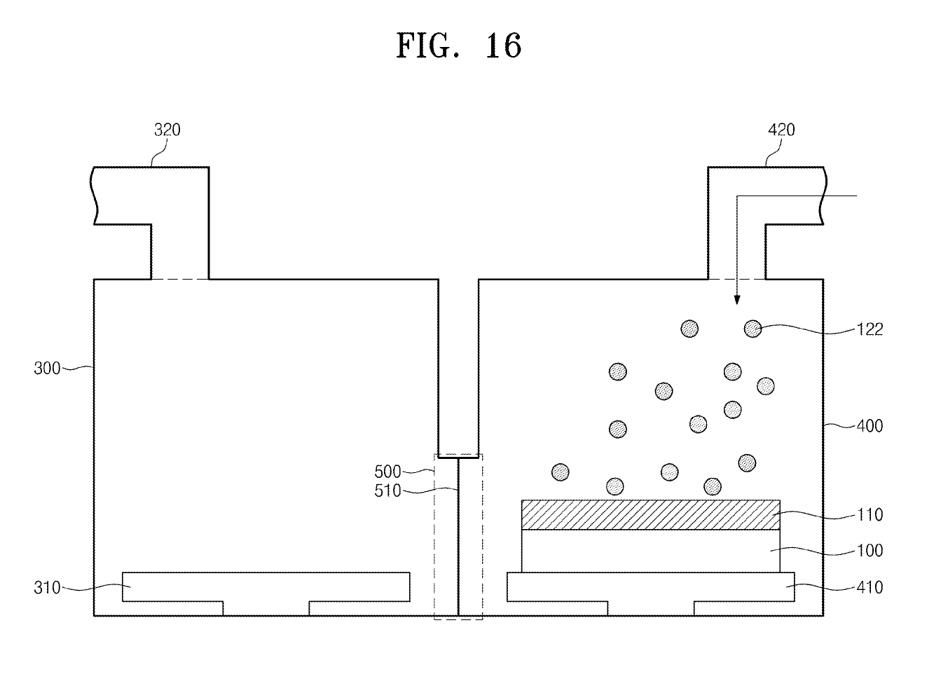

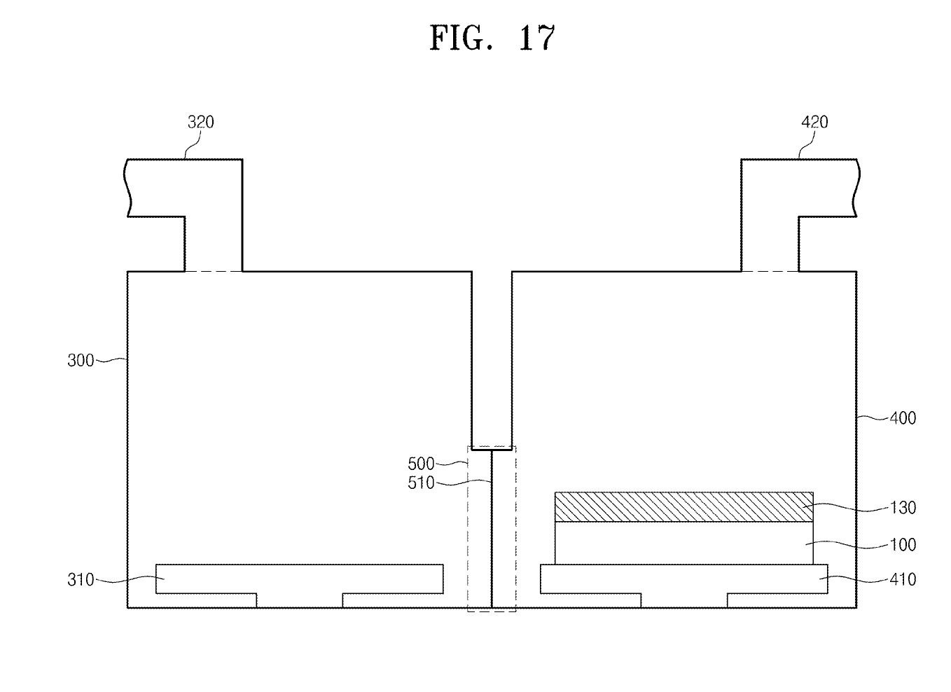

Referring to FIG. 16, a chalcogen material 122 may be provided on the transition metal film 110 from the chalcogen material supply device 420. The process of providing the chalcogen material 122 may be substantially same as the process of providing the chalcogen material 122 described with reference to FIGS. 9 to 12.

The transition metal film 110 and the chalcogen material 122 may be heated by the second substrate part 410. The heating process may be performed simultaneously with or after the provision of the chalcogen material 122. The heating process may be substantially same as the heating process described with reference to FIGS. 9 to 12. However, the substrate part 210 of the heating process of the application example described with reference to FIGS. 9 to 12 may be the second substrate part 410 of the present application example.

Referring to FIG. 17, a transition metal chalcogenide thin film 130 may be formed on a substrate 100. In one embodiment, the transition metal chalcogenide thin film 130 may be a MoS₂ thin film. The MoS₂ thin film may have a low-rise structure (for example, a mono-layer or a double-layer). The mono-layered MoS₂ thin film may include S atoms at lower and upper portions thereof and Mo atoms at a middle portion thereof. The Mo atoms may be covalently bonded to the adjacent S atoms. The MoS₂ film having an n layer structure may be formed as n number of mono-layered MoS₂ films are bonded by van der Waals bonding. MoS₂ having a low-rise structure may have excellent carrier mobility.

While this invention has been particularly shown and described with reference to preferred embodiments thereof, it will be understood by those skilled in the art that various changes in form and details may be made therein without departing from the spirit and scope of the invention as defined by the appended claims. The preferred embodiments should be considered in descriptive sense only and not for purposes of limitation. Therefore, the scope of the invention is defined not by the detailed description of the invention but by the appended claims, and all differences within the scope will be construed as being included in the present invention.

According to embodiments of the inventive concept, the chalcogen material is formed of a molecular structure having relatively less atoms to be provided on the substrate. In this case, since reactivity of the chalcogen material and the transition metal is enhanced, a transition metal chalcogenide thin film having a low-rise structure may be formed at a low temperature.

However, the effects of the inventive concept are not construed as limited to disclosed above.

The above-disclosed subject matter is to be considered illustrative and not restrictive, and the appended claims are intended to cover all such modifications, enhancements, and other embodiments, which fall within the true spirit and scope of the inventive concept. Thus, to the maximum extent allowed by law, the scope of the inventive concept is to be determined by the broadest permissible interpretation of the following claims and their equivalents, and shall not be restricted or limited by the foregoing detailed description.

What is claimed is:

1. A method of manufacturing a transition metal chalcogenide thin film, the method comprising:
providing a substrate having a transition metal film thereon; and
providing a chalcogen material having a first molecular structure on the transition metal film,
wherein the providing the chalcogen material having the first molecular structure comprises:
evaporating a chalcogen source to form a chalcogen material having a second molecular structure; and
decomposing the chalcogen material having the second molecular structure to form the chalcogen material having the first molecular structure,
wherein the first molecular structure comprises relatively less atoms than the second molecular structure.

2. The method of claim 1, further comprising performing a first heating process of the substrate.

3. The method of claim 2, wherein a temperature of the first heating process ranges from about 50° C. to about 550° C.

4. The method of claim 1, wherein the providing the chalcogen material having the first molecular structure is performed after the substrate having the transition metal film thereon is exposed to air.

5. The method of claim 1, wherein the evaporating the chalcogen source comprises performing a second heating process of the chalcogen source.

6. The method of claim 1, wherein the decomposing the chalcogen material having the second molecular structure comprises performing a third heating process of the chalcogen material having the second molecular structure,
wherein a temperature of the third heating process is higher than that of the second heating process.

7. The method of claim 1, wherein the transition metal film is a molybdenum (Mo) film.

8. The method of claim 1, wherein the chalcogen material is sulfur (S).

9. The method of claim 1, wherein the transition metal chalcogenide thin film comprises a structure of a mono-layer or a double layer.

10. A method of manufacturing a transition metal chalcogenide thin film, the method comprising providing a transition metal material and a chalcogen material having a first molecular structure on a substrate, wherein the providing the chalcogen material having the first molecular structure comprises:
evaporating a chalcogen source to form a chalcogen material having a second molecular structure; and
decomposing the chalcogen material having the second molecular structure to form the chalcogen material having the first molecular structure,
wherein the first molecular structure comprises relatively less atoms than the second molecular structure.

11. The method of claim 10, further comprising performing a first heating process of the substrate.

12. The method of claim 11, wherein a temperature of the first heating process ranges from about 50° C. to about 550° C.

13. The method of claim 10, wherein the evaporating the chalcogen source comprises performing a second heating process of the chalcogen source.

14. The method of claim 10, wherein the decomposing the chalcogen material having the second molecular structure comprises performing a third heating process of the chalcogen material having the second molecular structure,
wherein a temperature of the third heating process is higher than that of the second heating process.

15. The method of claim 10, wherein the transition metal material is molybdenum (Mo).

16. The method of claim 10, wherein the chalcogen material is sulfur (S).

17. The method of claim 10, wherein the transition metal chalcogenide thin film comprises a structure of a mono-layer or a double layer.
